(19) United States
(12) Patent Application Publication
(10) Pub. No.: US 2026/0237052 A1
(43) Pub. Date: Aug. 13, 2026

(54) METHOD OF FOCUS METROLOGY

(71) Applicant: ASML Netherlands B.V., Veldhoven (NL)

(72) Inventor: Wim Tjibbo TEL, Veldhoven (NL)

(73) Assignee: ASML Netherlands B.V., Veldhoven (NL)

(21) Appl. No.: 19/150,700

(22) PCT Filed: Dec. 26, 2023
(86) PCT No.: PCT/EP2023/087804

§ 371 Date: Jul. 24, 2025

(30) Foreign Application Priority Data
Jan. 25, 2023 (EP) 23153264.9

(51) Int. Cl. G06T 7/00; G06T 7/73

(52) U.S. Cl. CPC G06T 7/0006; G06T 7/001; G06T 7/73; G06T 2207/10061; G06T 2207/30164

(57) ABSTRACT

The present invention provides a method of focus metrology. The method comprises using an inspection tool to image a sample having a plurality of features formed by a lithography tool; determining the amount of shift of the plurality of features in the image of the sample in comparison to a design layout; and deriving a focus value of the lithography tool based on the amount of shift.

### CROSS-REFERENCE TO RELATED APPLICATION

This application claims priority of EP application 23153264.9 which was filed on 25 Jan. 2023 and which is incorporated herein in its entirety by reference.

### FIELD

The embodiments provided herein generally relate to an assessment system, a method of focus metrology and a computer-readable medium comprising instructions which, when executed by a computer, cause the computer to carry out the method of focus metrology.

### BACKGROUND

A lithographic apparatus (which may generally be referred to as a lithography tool) is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

When manufacturing semiconductor integrated circuit (IC) chips, for example with the use of a lithography tool, undesired pattern defects, as a consequence of, for example, optical effects and incidental particles, inevitably occur on a substrate (i.e. wafer) or a mask during the fabrication processes, thereby reducing the yield. Monitoring the extent of the undesired pattern defects is therefore an important process in the manufacture of IC chips. More generally, the assessment, e.g., inspection and/or measurement, of a surface of a substrate, or other object/material, is an important process during and/or after its manufacture.

Pattern assessment systems with a charged particle beam have been used to inspect objects, for example to detect pattern defects and to measure structural features on such objects. These tools typically use electron microscopy techniques, using electron optical systems for example in a scanning electron microscope (SEM). In exemplary electron optical system such a SEM, a primary electron beam of electrons at a relatively high energy is targeted with a final deceleration step in order to land on a sample at a relatively low landing energy. The beam of electrons is focused as a probing spot on the sample. The interactions between the material structure at the probing spot and the landing electrons from the beam of electrons cause electrons to be emitted from the surface, such as secondary electrons, backscattered electrons or Auger electrons. The generated secondary electrons may be emitted from the material structure of the sample. By scanning the primary electron beam as the probing spot over, or across, the sample surface, secondary electrons can be emitted across the surface of the sample. By collecting these emitted secondary electrons from the sample surface, a pattern assessment system (or assessment tool) may obtain an image representing characteristics of the material structure of the surface of the sample. The intensity of the electron beams comprising the backscattered electrons and the secondary electrons may vary based on the properties of the internal and external structures of the sample, and thereby may indicate whether the sample has defects.

When forming features on a sample using a lithography tool, the lithography tool should be appropriately focused on the sample such that features are formed with the desired shape and in the desired position, for example according to a design layout. One method to check the focus of the lithography tool is to manufacture a sample, by forming features on the sample using the lithography tool, and then to inspect the sample to determine the focus of the lithography tool. Typically, the task of focus metrology (i.e., determining the focus of the lithography tool used to form features on a sample) is performed using optical focus metrology methods, which make use of specially designed target features to determine whether the lithography tool is in focus and adjust the focus of the lithography tool if necessary before proceeding with manufacture of further samples. It can be difficult and time-consuming to design effective target features because the performance of the target feature as a means to establish focus is difficult to predict in advance, for example through simulations. This can result in a large amount of trial and error in order to arrive at an effective target feature. Furthermore, the specially designed target features often do not comply with design rules or constraints applied to production samples. This requires the use of dedicated samples used only for determining the focus of the lithography tool. There is therefore a desire to determine a method for determining focus of the lithography tool, using features of production samples as the target features.

### SUMMARY

It is an object of the present disclosure to provide embodiments of methods focus metrology.

According to a first aspect of the invention, there is provided a computer-readable medium comprising instructions which, when executed by a computer, cause the computer to carry out a method of focus metrology. The method comprises: imaging, using an inspection tool, a sample having a plurality of features formed by a lithography tool; determining the amount of shift of the plurality of features in the image of the sample in comparison to a design layout; and deriving a focus value of the lithography tool based on the amount of shift.

According to a second aspect of the invention, there is provided a method of focus metrology. The method comprises using an inspection tool to image a sample having a plurality of features formed by a lithography tool; determining the amount of shift of the plurality of features in the image of the sample in comparison to a design layout; and deriving a focus value of the lithography tool based on the amount of shift.

According to a third aspect of the invention, there is a method of focus metrology. The method comprises: imaging, using an inspection tool, a sample having a plurality of features formed by a lithography tool; determining the error in placement of the plurality of features in the image of the sample in comparison to the placement position of the plurality of features in a design layout; and deriving a focus value of the lithography tool based on the error in placement.

According to a fourth aspect of the invention, there is provided an assessment system comprising: an inspection tool, an image processing unit, and a focus determination unit. The inspection tool is configured to image a sample having a plurality of features formed by a lithography tool. The image processing unit configured to determine an amount of shift of the plurality of features in the image of the sample in comparison to a design layout. The focus determination unit configured to derive a focus value of the lithography tool based on the amount of shift.

Further embodiments, features and advantages of the present invention, as well as the structure and operation of the various embodiments, features and advantages of the present invention, are described in detail below with reference to the accompanying drawings.

### BRIEF DESCRIPTION OF FIGURES

The above and other aspects of the present disclosure will become more apparent from the description of exemplary embodiments, taken in conjunction with the accompanying drawings.

FIG. 1 is a schematic diagram illustrating an exemplary electron beam assessment apparatus.

FIG. 2 is a schematic diagram illustrating an exemplary multi-beam charged particle assessment system that is part of the exemplary electron beam assessment apparatus of FIG. 1.

FIG. 3A-B are schematic diagrams of a plurality of features, arranged in a 3×3 array having a central feature.

FIG. 4A is a schematic diagram illustrating a plurality of exemplary pattern groups in accordance with FIG. 3A, each pattern group comprising the central feature and an adjacent feature which is offset from the central feature in an orthogonal direction.

FIG. 4B is a schematic diagram illustrating a plurality of exemplary pattern groups in accordance with FIG. 3B, each pattern group comprising the central feature and an adjacent feature which is offset from the central feature in a diagonal direction.

FIG. 5A-O are graphs illustrating a relationship between focus value (on the X-axis) and amount of shift in the X-direction (on the Y-axis) for exemplary pattern groups of FIG. 4A.

FIG. 6 is a graph representing amount of shift in the X-direction for pattern groups of FIG. 5.

FIG. 7A-O are graphs illustrating a relationship between focus value (on the X-axis) and amount of shift in the Y-direction (on the Y-axis) for exemplary pattern groups of FIG. 4A.

The schematic diagrams and views show the components described below. However, the components depicted in the figures are not to scale.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims.

The enhanced computing power of electronic devices, which reduces the physical size of the devices, can be accomplished by significantly increasing the packing density of circuit components such as transistors, capacitors, diodes, etc. on an IC chip. This has been enabled by increased resolution enabling yet smaller structures to be made. For example, an IC chip of a smart phone, which is the size of a thumbnail and available in, or earlier than, 2019, may include over 2 billion transistors, the size of each transistor being less than 1/1000th of a human hair. Thus semiconductor IC manufacturing is a complex and time-consuming process, with many individual steps. An error in one of these steps has the potential to significantly influence the functioning of the final product. The goal of the manufacturing process is to improve the overall yield of the process. For example, to obtain a 75% yield for a 50-step process (where a step can indicate the number of layers formed on a wafer), each individual step must have a yield greater than 99.4%. If each individual step had a yield of 95%, the overall process yield would be as low as 7%.

While high process yield is desirable in an IC chip manufacturing facility, maintaining a high substrate (i.e. wafer) throughput, defined as the number of substrates processed per hour, is also essential. High process yield and high substrate throughput can be impacted by the presence of a defect. This is especially true if operator intervention is required for reviewing the defects. Thus, high throughput detection and identification of micro and nano-scale defects by assessment systems (such as, or such as comprising, a Scanning Electron Microscope (‘SEM’)) is essential for maintaining high yield and low cost.

A SEM comprises a scanning device and a detector apparatus. The scanning device comprises an illumination apparatus that comprises an electron source, for generating primary electrons, and a projection apparatus for scanning a sample, such as a substrate, with one or more focused beams of primary electrons. Together at least the illumination apparatus, or illumination system, and the projection apparatus, or projection system, may be referred to together as the electron-optical system or apparatus. The primary electrons interact with the sample and generate secondary electrons. The detection apparatus captures the secondary electrons from the sample as the sample is scanned so that the SEM can create an image of the scanned area of the sample. Such an assessment apparatus may utilize a single primary electron beam incident on a sample. For high throughput inspection, some of the assessment apparatuses use multiple focused beams, i.e. a multi-beam, of primary electrons. The component beams of the multi-beam may be referred to as sub-beams or beamlets. The sub-beams may be arranged with respect to each other within the multi-beam in a multi-beam arrangement. A multi-beam can scan different parts of a sample simultaneously. A multi-beam assessment apparatus can therefore assess, for example inspect, a sample at a much higher speed than a single-beam assessment apparatus.

An implementation of known multi-beam assessment apparatus and systems is described below.

The figures are schematic. Relative dimensions of components in drawings are therefore exaggerated for clarity. Within the following description of drawings the same or like reference numbers refer to the same or like components or entities, and only the differences with respect to the individual embodiments are described. While the description and drawings are directed to an electron-optical system, it is appreciated that the embodiments are not used to limit the present disclosure to specific charged particles. References to electrons throughout the present document may therefore be more generally be considered to be references to charged particles, with the charged particles not necessarily being electrons.

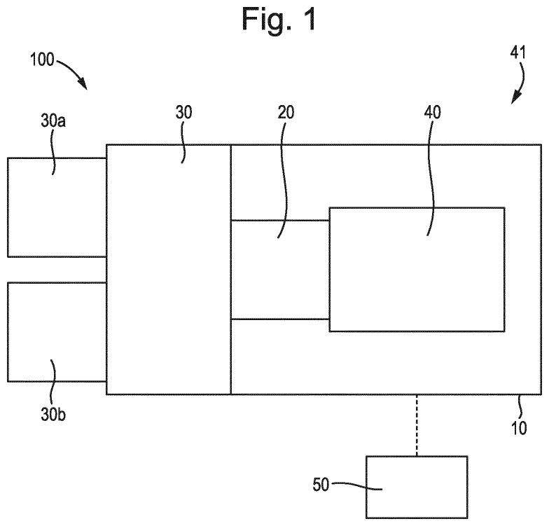

Reference is now made to FIG. 1, which is a schematic diagram illustrating an exemplary charged particle beam assessment apparatus 100. It should be noted that the assessment apparatus comprises part of the assessment system, often the part of the assessment system situated in a fabrication facility. The assessment apparatus may cover a surface area of the fabrication facility floor referred to as an apparatus footprint. The other parts of the assessment system such as service systems of vacuum and fluid supplies and remote processing racks may be located elsewhere in the fabrication facility away from other fabrication systems and apparatus where space is a less significant requirement,

The charged particle beam assessment apparatus 100 of FIG. 1 includes a main chamber 10, a load lock chamber 20, a charged particle assessment system 40 (which may also be called an electron beam system or tool), an equipment front end module (EFEM) 30 and a controller 50. The charged particle assessment system 40 is located within the main chamber 10.

The EFEM 30 includes a first loading port 30a and a second loading port 30b. The EFEM 30 may include additional loading port(s). The first loading port 30a and the second loading port 30b may, for example, receive substrate front opening unified pods (FOUPs) that contain substrates (e.g., semiconductor substrates or substrates made of other material(s)) or samples to be assessed e.g. measured or inspected (substrates, wafers and samples are collectively referred to as “samples” hereafter). One or more robot arms (not shown) in the EFEM 30 transport the samples to the load lock chamber 20.

The load lock chamber 20 is used to remove the gas around a sample. This creates a vacuum that is a local gas pressure lower than the pressure in the surrounding environment. The load lock chamber 20 may be connected to a load lock vacuum pump system (not shown), which removes gas particles in the load lock chamber 20. The operation of the load lock vacuum pump system enables the load lock chamber to reach a first pressure below the atmospheric pressure. After reaching the first pressure, one or more robot arms (not shown) transport the sample from the load lock chamber 20 to the main chamber 10. The main chamber 10 is connected to a main chamber vacuum pump system (not shown). The main chamber vacuum pump system removes gas particles in the main chamber 10 so that the pressure in around the sample reaches a second pressure lower than the first pressure. After reaching the second pressure, the sample is transported to the charged particle assessment system 40 by which it may be assessed. The charged particle assessment system 40 comprises a charged particle device 41. The charged particle device 41 may be an electron-optical device, which may be synonymous with the electron-optical system. The charged particle device 41 may be a multi-beam charged particle device 41 configured to project a multi-beam towards the sample, for example the sub-beams being arranged with respect to each other in a multi-beam arrangement. Alternatively, the charged particle device 41 may be a single beam charged particle device 41 configured to project a single beam towards the sample.

The controller 50 is electronically connected to the charged particle assessment system 40. The controller 50 may be a processor (such as a computer) configured to control the charged particle beam assessment apparatus 100. The controller 50 may also include a processing circuitry configured to execute various signal and image processing functions. While the controller 50 is shown in FIG. 1 as being outside of the structure that includes the main chamber 10, the load lock chamber 20, and the EFEM 30, it is appreciated that the controller 50 may be part of the structure. The controller 50 may be located in one of the component elements of the charged particle beam assessment apparatus or it can be distributed over at least two of the component elements. While the present disclosure provides examples of the main chamber 10 housing an electron beam assessment apparatus, it should be noted that aspects of the disclosure in their broadest sense are not limited to a chamber housing an electron beam assessment apparatus. Rather, it is appreciated that the foregoing principles may also be applied to other tools and other arrangements of apparatus, that operate under the second pressure.

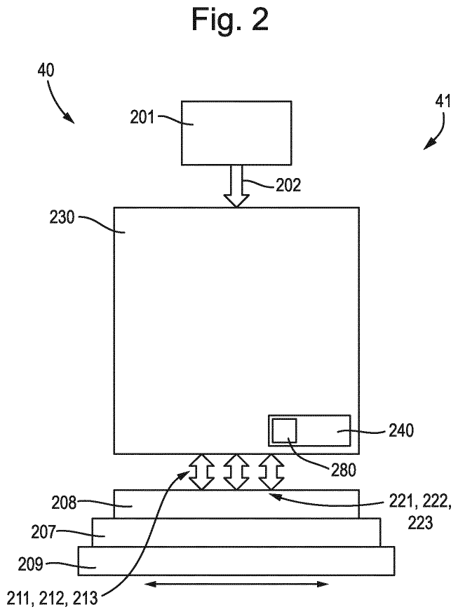

Reference is now made to FIG. 2, which is a schematic diagram illustrating an exemplary charged particle assessment system 40 including a multi-beam charged particle device 41 that is part of the exemplary charged particle beam assessment apparatus 100 of FIG. 1. The multi-beam charged particle device 41 comprises an electron source 201 and a projection apparatus 230. The charged particle assessment system 40 further comprises an actuated stage 209 and a sample holder 207. The sample holder may have a holding surface (not depicted) for supporting and holding the sample. Thus the sample holder may be configured to support the sample. Such a holding surface may be a electrostatic clamp operable to hold the sample during operation of the charged particle device 41 e.g. assessment such as measurement or inspection of at least part of the sample. The holding surface may be recessed into sample holder, for example a surface of the sample holder orientated to face the charged particle device 41. The electron source 201 and projection apparatus 230 may together be referred to as the charged particle device 41. The sample holder 207 is supported by actuated stage 209 so as to hold a sample 208 (e.g., a substrate or a mask) for assessment. The multi-beam charged particle device 41 further comprises a detector 240 (e.g. an electron detection device).

The electron source 201 may comprise a cathode (not shown) and an extractor or anode (not shown). During operation, the electron source 201 is configured to emit electrons as primary electrons from the cathode. The primary electrons are extracted or accelerated by the extractor and/or the anode to form a primary electron beam 202.

The projection apparatus 230 is configured to convert the primary electron beam 202 into a plurality of sub-beams 211, 212, 213 and to direct each sub-beam onto the sample 208. Although three sub-beams are illustrated for simplicity, there may be many tens, many hundreds or many thousands of sub-beams. The sub-beams may be referred to as beamlets.

The controller 50 may be connected to various parts of the charged particle beam assessment apparatus 100 of FIG. 1, such as the electron source 201, the detector 240, the projection apparatus 230, and the actuated stage 209. The controller 50 may perform various image and signal processing functions. The controller 50 may also generate various control signals to govern operations of the charged particle beam assessment apparatus, including the charged particle multi-beam apparatus.

The projection apparatus 230 may be configured to focus sub-beams 211, 212, and 213 onto a sample 208 for assessment and may form three probe spots 221, 222, and 223 on the surface of sample 208. The projection apparatus 230 may be configured to deflect the primary sub-beams 211, 212, and 213 to scan the probe spots 221, 222, and 223 across individual scanning areas in a section of the surface of the sample 208. In response to incidence of the primary sub-beams 211, 212, and 213 on the probe spots 221, 222, and 223 on the sample 208, electrons are generated from the sample 208 which include secondary electrons and backscattered electrons. The secondary electrons typically have electron energy ≤50 eV. Actual secondary electrons can have an energy of less than 5 eV, but anything beneath 50 eV is generally treated at a secondary electron. Backscattered electrons typically have electron energy between 0 eV and the landing energy of the primary sub-beams 211, 212, and 213. As electrons detected with an energy of less than 50 eV is generally treated as a secondary electron, a proportion of the actual backscatter electrons will be counted as secondary electrons.

The detector 240 is configured to detect signal particles such as secondary electrons and/or backscattered electrons and to generate corresponding signals which are sent to a signal processing system 280, e.g. to construct images of the corresponding scanned areas of sample 208. The detector 240 may be incorporated into the projection apparatus 230.

The signal processing system 280 may comprise a circuit (not shown) configured to process signals from the detector 240 so as to form an image. The signal processing system 280 could otherwise be referred to as an image processing system. The signal processing system may be incorporated into a component of the multi-beam charged particle assessment system 40 such as the detector 240 (as shown in FIG. 2). However, the signal processing system 280 may be incorporated into any components of the assessment apparatus 100 or multi-beam charged particle assessment system 40, such as, as part of the projection apparatus 230 or the controller 50. The signal processing system 280 may include an image acquirer (not shown) and a storage device (not shown). For example, the signal processing system may comprise a processor, computer, server, mainframe host, terminals, personal computer, any kind of mobile computing devices, and the like, or a combination thereof. The image acquirer may comprise at least part of the processing function of the controller. Thus the image acquirer may comprise at least one or more processors. The image acquirer may be communicatively coupled to the detector 240 permitting signal communication, such as an electrical conductor, optical fiber cable, portable storage media, IR, Bluetooth, internet, wireless network, wireless radio, among others, or a combination thereof. The image acquirer may receive a signal from the detector 240, may process the data comprised in the signal and may construct an image therefrom. The image acquirer may thus acquire images of the sample 208. The image acquirer may also perform various post-processing functions, such as generating contours, superimposing indicators on an acquired image, and the like. The image acquirer may be configured to perform adjustments of brightness and contrast, etc. of acquired images. The storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

The signal processing system 280 may include measurement circuitry (e.g., analog-to-digital converters) to obtain a distribution of the detected secondary electrons. The electron distribution data, collected during a detection time window, can be used in combination with corresponding scan path data of each of primary sub-beams 211, 212, and 213 incident on the sample surface, to reconstruct images of the sample structures under assessment. The reconstructed images can be used to reveal various features of the internal or external structures of the sample 208. The reconstructed images can thereby be used to reveal any defects that may exist in the sample.

The controller 50 may control the actuated stage 209 to move sample 208 during assessment, e.g. inspection, of the sample 208. The controller 50 may enable the actuated stage 209 to move the sample 208 in a direction, preferably continuously, for example at a constant speed, at least during sample assessment. The controller 50 may control movement of the actuated stage 209 so that it changes the speed of the movement of the sample 208 dependent on various parameters. For example, the controller 50 may control the stage speed (including its direction) depending on the characteristics of the assessment steps of scanning process.

Known multi-beam systems, such as the charged particle assessment system 40 and charged particle beam assessment apparatus 100 described above, are disclosed in US2020118784, US 20200203116, US 2019/0259570 and US2019/0259564 which are hereby incorporated by reference.

As shown in FIG. 2, in an embodiment the charged particle assessment system 40 has a single charged particle device 41 and optionally comprises a projection assembly 60. The projection assembly 60 may be a module and may be referred to as an ACC module. The projection assembly 60 is arranged to direct a light beam 62 such that the light beam 62 enters between the charged particle device 41 and the sample 208.

When the electron beam scans the sample 208, charges may be accumulated on the sample 208 due to large beam current, which may affect the quality of the image. To regulate the accumulated charges on the sample, the projection assembly 60 may be employed to illuminate the light beam 62 on the sample 208, so as to control the accumulated charges due to effects such as photoconductivity, photoelectric, or thermal effects.

A lithographic apparatus is a machine that applies a desired pattern onto a substrate, usually onto a target portion of the substrate, in order to form a sample (and such a sample may then undergo inspection by an assessment apparatus, for example as shown in FIG. 2).

A patterning device may be used to generate a circuit pattern to be formed on an individual layer of the substrate. The term “patterning device” should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit. In particular, the pattern may be in accordance with a design layout which defines the desired shape and position of features to be formed on the sample. In order to form the features on the sample with an acceptable level of accuracy, the lithography tool should be correctly configured and calibrated. In particular, the lithography tool should be focused on a target surface of the sample to form the features on the target surface of the sample. In other words, the lithography tool should focus the radiation beam onto the target portion on the sample.

As described above, a charged particle assessment system 40, for example that of FIG. 2, may include an assessment tool which may also be referred to as an inspection tool, used to inspect a sample in order to detect any defects on the sample. In particular, the inspection tool may be used to inspect a sample to determine the focus of the inspection tool used to form the features on the sample. If it is determined that the inspection tool is not in focus, the focus of the lithography tool may be adjusted before further samples are manufactured using the lithography tool.

The inspection tool is used to image the sample. There are a plurality of features on the sample. In particular, the inspection tool may image the sample to generate an image depicting a plurality of features. The features optionally include contact holes defined by the sample. For example, there may be contact holes in the facing surface of the sample.

The image is used to determine the amount of shift of the plurality of features in the image of the sample in comparison to a design layout. The design layout is a representation of the intended layout of features on the sample. In other words, the design layout defines the target positions for the features of the sample. In this way, comparison between the position of the features in the design layout and the position of the features in the image taken by the inspection tool can be used to establish an error in the position of the features in the image. The error in position being a difference between the position of the features in the image and the intended position of those features as defined by the design layout. This error in position of the features may be considered as an amount of offset or an amount of shift of the position of the features compared to the expected and intended position which is defined by the design layout.

For any individual feature, there may be an error in position that is due at least in part to a defect on the sample, for example that feature may be missing or misshapen. As such the error in position of a single feature is not necessarily indicative of the lithography tool being poorly focused on the sample when the lithography tool was forming the feature on sample. In order to reduce the influence of actual defects on the amount of shift, a sufficient number of features should be included in the image. For example, there may be over 100 features, preferably over 500 feature, more preferably over 1,000 features captured by the image. The greater the number of features, the lower the influence on the amount of shift of errors in position caused by defects on the sample. It is desirable that the field of view of the inspection tool is wide enough to encompass the majority of the sample, and desirably the entire sample. In this way the image may depict the entirety, or at least a majority, of the features on the sample.

A focus value of the lithography tool is derived based on the amount of shift.

The method of any of the preceding claims, wherein the inspection tool may comprises a charged particle device, for example such as the charged particle device 41 of FIG. 2. The charged particle device may be a device configured to project beams of electrons towards the sample. The charge particle device desirably comprises a scanning electron microscope.

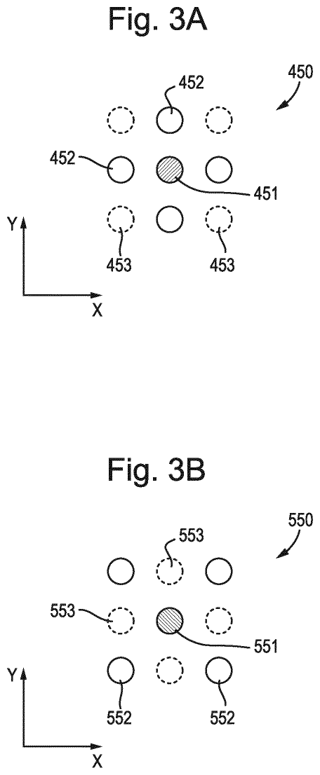

The plurality of features optionally form a repeating pattern group on the sample. The image may depict over 500 instances of the pattern group, desirably over 1,000 instances of the pattern group, more desirably over 2,000, and yet more desirably the image depicts over 4,000 instances of the pattern group. FIGS. 3A and 3B are schematic diagrams of a plurality of features, arranged in a 3×3 array in an X-Y plane. A pattern group may be selected from the features of the 3×3 array. For example, as shown in FIGS. 3A and 3B, the features included in the pattern group 450, 550 may include a central feature 451, 551 and one or more of the adjacent features 452, 453, 552, 553. In FIGS. 3A and 3B the adjacent features 452, 453, 552, 553 surround the central feature 451, 551. In an alternative arrangement, the pattern group may be a single pair of features, in other words a central feature and a single adjacent feature without the remaining features of the 3×3 arrays of FIGS. 3A and 3B being present on the sample.

In an arrangement wherein the plurality of features form a repeating pattern group on the sample, determining the amount of shift may comprise comparing the position of the features in each instance of the pattern group in the image with the position of the corresponding features in each instance of the pattern group in the design layout. Determining the amount of shift may further comprise using this comparison to determine an average position offset of the features in each instance of the pattern group in the image.

The focus value may be derived based on a predetermined relationship between focus value and amount of shift of the plurality of features in the image. In an arrangement wherein the plurality of features form a repeating pattern group on the sample, the focus value may be derived based on a predetermined relationship between focus value and amount of shift of the plurality of features in the image for the pattern group. In other words, there exist pattern groups for which there is a relationship between the amount of shift and the focus value. For example, the amount of shift, or the error in placement, of features in the image may increase with increasing focus value. In this way it may be determined whether or not the lithography tool was appropriately focused on the surface of the sample during formation of the features based on the amount of shift determined in the features depicted in the image captured by the inspection tool, when compared to the design layout.

The predetermined relationship between focus value and amount of shift may be determined based on a simulation. For example, the effects of defocusing the lithography tool may be investigated using a simulated lithography tool, modelled on a computer. A simulated sample may be generated by forming features on the simulated sample using the simulated lithography tool. The simulated lithography tool may be configured to have a particular focus value, and to attempt to form the features on the simulated sample based on the design layout. The resulting simulated sample may be used to determine an amount of shift of the features of the simulated sample.

The simulation may be repeated such that a series of simulations is performed, where in each simulation the lithography tool is set at a different focus value for forming the features on the simulated sample. In this way, for each of a plurality of different focus values, a simulated sample is generated and a corresponding amount of shift can be determined. Desirably, for each focus value of the simulated lithography tool, a corresponding amount of shift of the plurality of features in the pattern group on the simulated sample is determined. In this way the relationship between focus value of the lithography tool and amount of shift of the pattern group can be established.

It may be desirable to perform the series of simulations, corresponding to different focus values, for a plurality of different pattern groups. In this way, it may be determined which pattern group of the plurality of different patter groups has an amount of shift which is sensitive to changes in focus value. This may have the benefit of enabling a suitable pattern group to be identified from among the possible pattern groups on a design layout of a sample to be produced. This may enable focusing of the lithography tool to be performed on production samples rather than a dedicated focusing, or calibration, sample having a specifically designed target feature. Focusing of the lithography tool may therefore be performed more efficiently, which may desirably increase throughput of samples being inspected.

Alternatively, or in addition, to determining the predetermined relationship between focus value and amount of shift based on simulations, the predetermined relationship may be determined by practical experimentation. A lithographic tool set to a selected focus value may be used to form a plurality of features on a calibration sample based on a design layout. The amount of shift of the plurality of features in the calibration sample in comparison to the design layout may then be determined by any known measurement method of sufficient precision. Desirably, the amount of shift of the plurality of features in a pattern group of the calibration sample is determined.

The experiment may be repeated such that a series of experiments is performed, where in each experiment the lithography tool set at a different focus value for forming features on the calibration sample. In this way, for each of a plurality of different focus values, a corresponding calibration sample is generated and a corresponding amount of shift can be determined. Desirably, for each focus value of the lithography tool, a corresponding amount of shift of the plurality of features in the image for the pattern group is determined. In this way the relationship between focus value of the inspection tool and amount of shift of the pattern group can be established.

Similarly to the process of determining the predetermined relationship between focus value and amount of shift based on simulations, the process of the predetermined relationship may be determined by practical experimentation may be repeated for different pattern groups. In this way the most suitable pattern group, having an amount of shift which is sensitive to changes in the focus value of the lithography tool, may be identified. The identified suitable pattern group may then be used to determine the focus of the lithography tool by inspection of production samples.

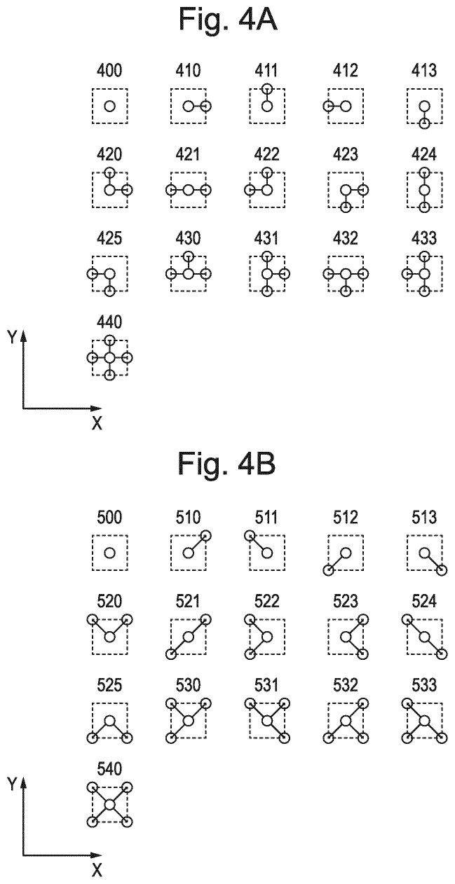

FIG. 4A is a schematic diagram illustrating a plurality of exemplary pattern groups in accordance with FIG. 3A. Each instance of the pattern group 450 of FIGS. 3A and 4A comprises the central feature 451. For example, the exemplary pattern group 400 in the top left of FIG. 4A consists of the central feature. As described above in reference to FIGS. 3A and 3B, each instance of the pattern group desirably comprises at least two adjacent features. Each of the exemplary pattern groups 410-413 in the top row (other than exemplary pattern group 400 in the top left) of FIG. 4A comprises the central feature 451 and an adjacent feature 452 which is offset from the central feature in an orthogonal direction on the sample, such as the X-direction or the Y-direction. In particular, the adjacent feature 452 which is offset from the central feature is desirably offset in an orthogonal direction in the image of the sample.

As shown in FIG. 3A and FIG. 4A, the exemplary pattern group may comprise the central feature 451 and one or more adjacent features 452 offset from the central feature in an orthogonal direction. For example, the exemplary pattern group may comprise the central feature 451 and up to four adjacent features 452, wherein each of the up to four adjacent features 452 is offset from the central feature in a different orthogonal direction than the other adjacent features 452. For example, the exemplary pattern groups 420-424 on the second row from the top and the leftmost pattern group 425 in the third row from the top in FIG. 4A each consist of the central feature and two adjacent features. For example, the remaining exemplary pattern groups 430-433 in the third row from the top of FIG. 4A each consist of the central feature and two adjacent features. As a further example, the exemplary pattern group 440 in the bottom left of FIG. 4A consists of the central feature and four adjacent features.

FIG. 4B is a schematic diagram illustrating a plurality of exemplary pattern groups in accordance with FIG. 3B. Each instance of the pattern group 550 of FIGS. 3B and 4B comprises the central feature 551. For example, the exemplary pattern group 500 in the top left of FIG. 4B consists of the central feature (and is therefore the same pattern as exemplary pattern group 400 in the top left of FIG. 4A). As described above in reference to FIGS. 3A and 3B, each instance of the pattern group desirably comprises at least two adjacent features. Each of the exemplary pattern groups 510-513 in the top row (other than exemplary pattern group 500 in the top left) of FIG. 4B comprises the central feature 551 and an adjacent feature 552 which is offset from the central feature in a diagonal direction on the sample. In particular, the adjacent feature 552 which is offset from the central feature is desirably offset in a diagonal direction in the image of the sample.

As shown in FIG. 3B and FIG. 4B, the exemplary pattern group may comprise the central feature 551 and one or more adjacent features 552 offset from the central feature in a diagonal direction. For example, the exemplary pattern group may comprise the central feature 551 and up to four adjacent features 552, wherein each of the up to four adjacent features 552 is offset from the central feature in a different diagonal direction than the other adjacent features 552. For example, the exemplary pattern groups 520-524 on the second row from the top and the leftmost pattern group 425 in the third row from the top in FIG. 4B each consist of the central feature and two adjacent features. For example, the remaining exemplary pattern groups 530-533 in the third row from the top of FIG. 4B each consist of the central feature and two adjacent features. As a further example, the exemplary pattern group 540 in the bottom left of FIG. 4B consists of the central feature and four adjacent features.

As described above, simulations or experimentation can be used to identify a pattern group having an amount of shift which is highly sensitive to changes in the focus value of the lithography tool. In other words, a pattern group may be designed, for example by simulation. The designed pattern group contains one or more features that will be highly sensitive to focus induced pattern shift. In this way, the amount of shift in each instance of the pattern can be used to derive the focus value of the lithography tool, with sufficient accuracy to aid in focusing the lithography tool on the sample to form features on the sample at positions which match the design layout to within an acceptable threshold.

In particular, the predetermined relationship between focus value and amount of shift may be determined, for example by simulation or experimentation as described above. The predetermined relationship is determined for a plurality of possible pattern groups. The pattern group to be used to determine focus of the lithography tool can then be selected from the plurality of possible pattern groups (for which the predetermined relationship has been determined) based on sensitivity of focus value to amount of shift for each of plurality of possible pattern groups.

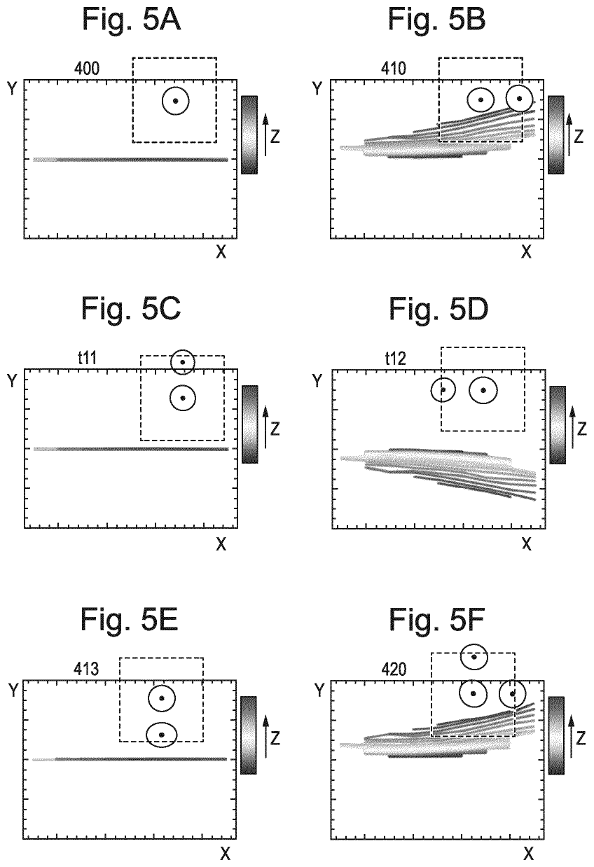

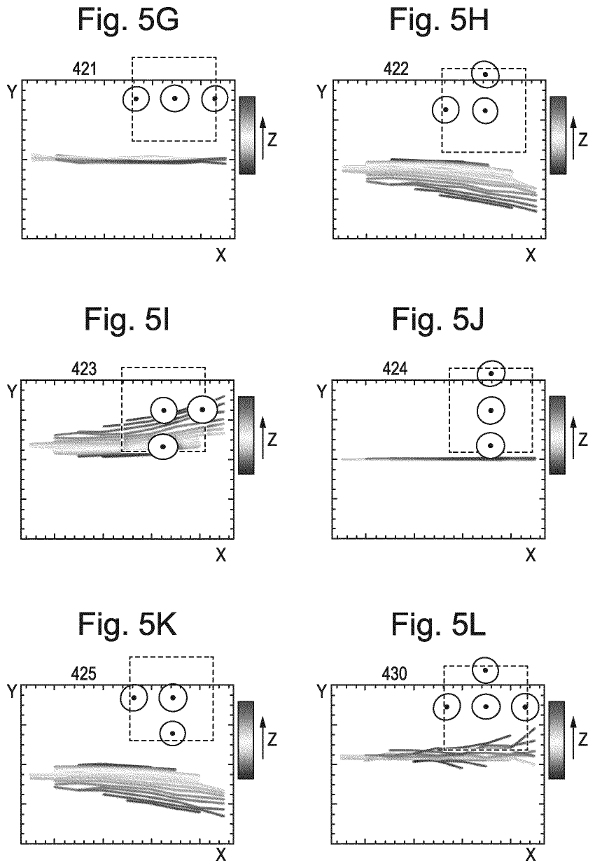

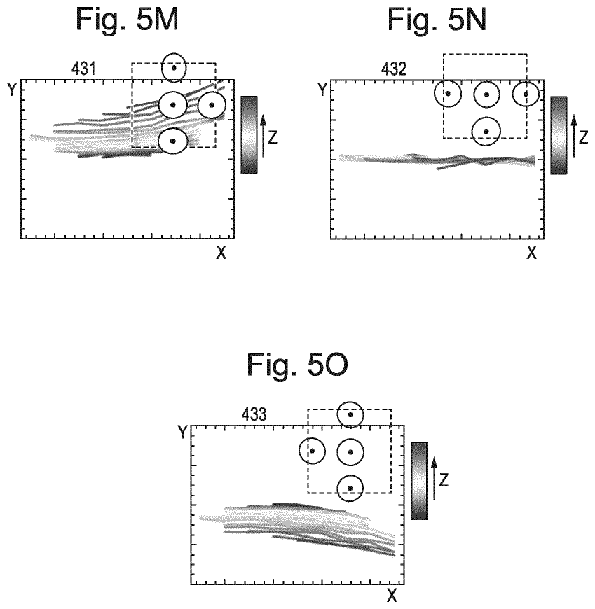

FIG. 5A-O are graphs illustrating the relationship between focus value (on the X-axis) and amount of shift in the X-direction (on the Y-axis) for exemplary pattern groups of FIG. 4A. In particular, FIG. 5A-O provides the predetermined relationship (as determined by simulation) regarding amount of shift in the X-direction for a selection of the exemplary pattern groups 400-433 of FIG. 4A.

From the predetermined relationships illustrated by the graphs of FIG. 5A-O, it can be observed that some of the pattern groups, for exemplary pattern group 400 of FIG. 5A and pattern group 411 of FIG. 5C, do not demonstrate a high sensitivity between changes in the focus value (on the X-axis) and amount of shift based on placement error of the features in the X-direction (on the Y-axis). As such, if considering the amount of shift of the pattern groups in the X-direction, exemplary pattern group 400 of FIG. 5A and pattern group 411 of FIG. 5C would not be the most suitable pattern groups to use. In other words, if the exemplary pattern group 400 of FIG. 5A or pattern group 411 of FIG. 5C were selected as the pattern group to be used in the process of determining the focus of the lithography tool, the amount of shift in the X-direction would not be a useful indicator of the focus value of the lithography tool, because the amount of shift in the X-direction for these exemplary patterns does not change significantly based on the focus value of the lithography tool.

The graphs of FIG. 5A-O also include information regarding how the relationship between focus value (on the X-axis) and amount of shift in the X-direction (on the Y-axis) vary with varying dose (as shown by range Z). For example, FIG. 5B shows that for exemplary pattern group 410, the focus value is sensitive to changes in dose as well as to amount of shift in the X-direction. This means that the focus value may be determined based on the amount of shift only if the dose is also taken into account as part of the relationship. It is therefore desirable, where possible, to identify a pattern group for which the focus value is less sensitive to the dose, such that the amount of shift can be used as a sufficiently accurate indication of focus value without necessarily requiring the dose to also be considered.

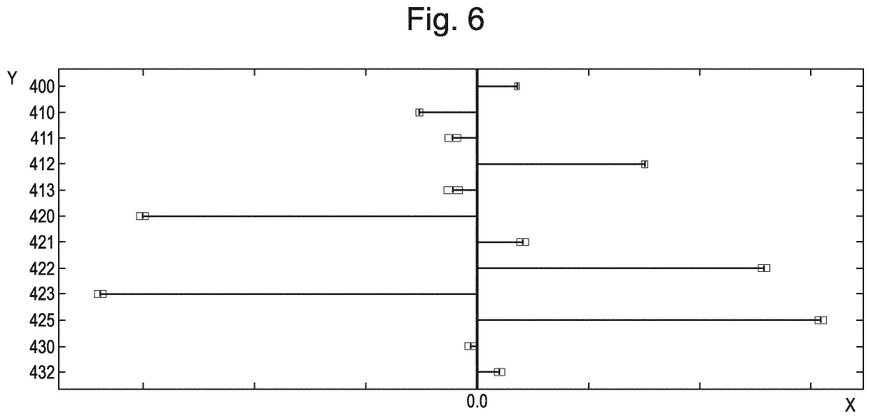

FIG. 6 is a graph representing amount of shift in the X-direction (on the X-axis) for pattern groups of FIG. 5 (as listed on the Y-axis). This confirms that the pattern groups, for exemplary pattern group 400 and pattern group 411 do not demonstrate a high sensitivity between changes in the focus value and placement error of the features in the X-direction. In contrast, exemplary pattern groups such as pattern group 123 (having a central feature, a feature to the left and a feature below), demonstrates a greater placement error in the X-direction.

FIG. 6 also includes the confidence interval for placement error in the X-direction for each pattern group. For example, a confidence interval of <0.01 nm has been demonstrated for pattern group 123 (having a central feature, a feature to the left and a feature below).

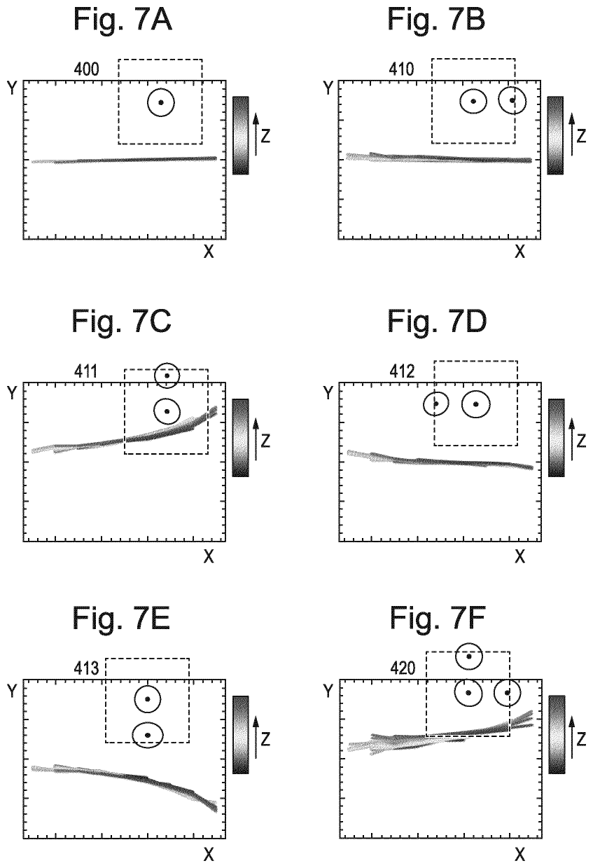

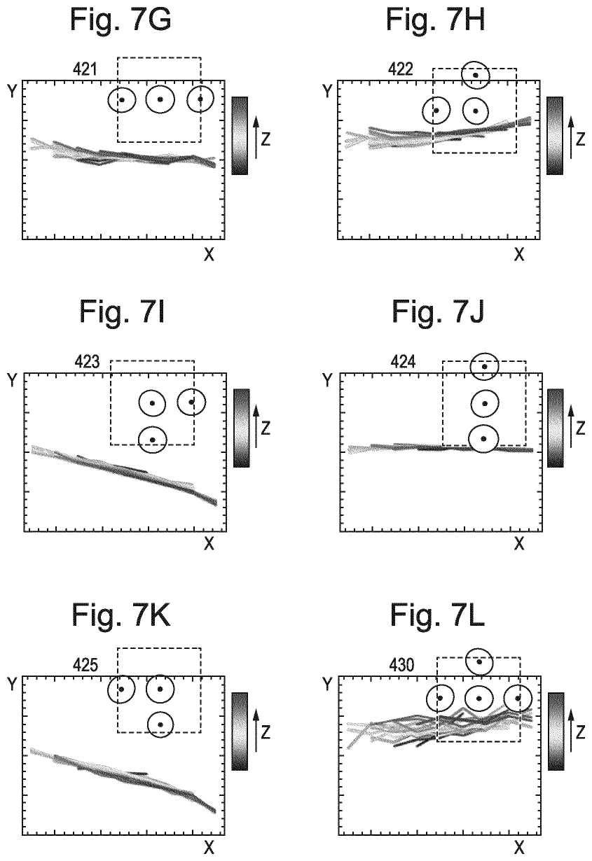

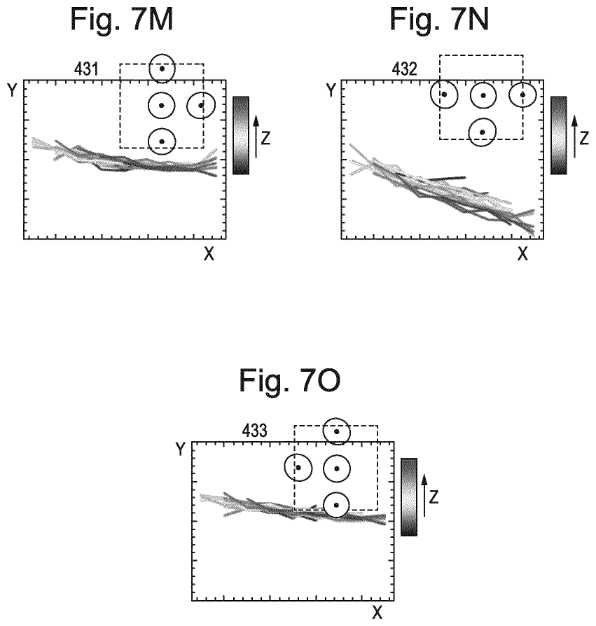

FIG. 7A-O are graphs illustrating a relationship between focus value (on the X-axis) and amount of shift in the Y-direction (on the Y-axis) for exemplary pattern groups of FIG. 4A. In particular, FIG. 7A-O provides the predetermined relationship (as determined by simulation) regarding amount of shift in the Y-direction for a selection of the exemplary pattern groups 400-433 of FIG. 4A.

From the predetermined relationships illustrated by the graphs of FIG. 7A-O, it can be observed that some of the pattern groups, for exemplary pattern group 400 of FIG. 7A and pattern group 410 of FIG. 7B, do not demonstrate a high sensitivity between changes in the focus value (on the X-axis) and amount of shift based on placement error of the features in the Y-direction (on the Y-axis). As such, if considering the amount of shift of the pattern groups in the Y-direction, exemplary pattern group 400 of FIG. 7A and pattern group 410 of FIG. 7B would not be the most suitable pattern groups to use. In other words, if the exemplary pattern group 400 of FIG. 7A or pattern group 410 of FIG. 7B were selected as the pattern group to be used in the process of determining focus of the lithography tool, the amount of shift in the Y-direction would not be a useful indicator of the focus value of the lithography tool, because the amount of shift in the Y-direction for these exemplary patterns does not change significantly based on the focus value of the lithography tool. In contrast, FIG. 7C shows that pattern group 411 of FIG. 7C, demonstrates a high sensitivity between changes in the focus value (on the X-axis) and amount of shift based on placement error of the features in the Y-direction (on the Y-axis).

The graphs of FIG. 7A-O also include information regarding how the relationship between focus value (on the X-axis) and amount of shift in the Y-direction (on the Y-axis) vary with varying dose (as shown by range Z). For example, FIG. 7L shows that for exemplary pattern group 430, the focus value is sensitive to changes in dose as well as to amount of shift in the Y-direction. This means that the focus value may be determined based on the amount of shift only if the dose is also taken into account as part of the relationship. In contrast, FIG. 7C shows that for exemplary pattern group 411 (which comprises the central feature and a feature directly above the central feature), the focus value is not sensitive to changes in dose as well as to amount of shift in the Y-direction. Instead, the amount of shift in the Y-direction generally increases with increasing focus value, with little variation due to change in does. Using the pattern group 411 of FIG. 7C, the amount of shift in the Y-direction may be used as a sufficiently accurate indication of focus value without necessarily requiring the dose to also be considered. Thus, the simulation results shown in the graphs of FIG. 5A-O and FIG. 7A-O enable pattern group 411 of FIG. 7C to be identified as a suitable pattern group for use in determining focus of the lithography tool, by considering amount of shift in the Y-direction. Thus, the simulation results shown in FIG. 5A-O and FIG. 7A-O enable a suitable pattern group to be selected from a plurality of possible pattern groups.

The process for determining focus of the lithography tool optionally further comprises selecting an additional pattern group, in addition to a first selected pattern group, from the plurality of different possible pattern groups. The additional pattern group is desirably selected based on the predetermined relationship for the additional pattern group being generally the inverse of the predetermined relationship for the pattern group. For example, as described above, the pattern group 411 of FIG. 7C may be suitable to be selected as the first selected pattern group for using in the process for determining focus of the lithography tool. As the additional pattern group, pattern group 413 of FIG. 7E may be selected. In FIG. 7C it is shown that for pattern group 411, the amount of shift in the Y-direction generally increases with increasing focus value. Whereas, in FIG. 7E it is shown that for pattern group 413, the amount of shift in the Y-direction generally increases with increasing focus value. As such, the predetermined relationship for pattern group 413 of FIG. 7E is generally the inverse of the predetermined relationship for the pattern group 411 of FIG. 7C, and vice versa. The use of multiple pattern groups may beneficially enable the focus value to be more accurately determined.

The process for determining focus of the lithography tool optionally further using the selected additional pattern group may comprise comparing the position of the features in each instance of the additional pattern group in the image with the position of the corresponding features in each instance of the additional pattern group in the design layout to determine an average position offset in each instance of the additional pattern group in the image. Similarly, the average position offset may also be determine for the first selected pattern group. In particular, by comparing the position of the features in each instance of the first pattern group in the image with the position of the corresponding features in each instance of the first pattern group in the design layout to determine an average position offset in each instance of the first pattern group in the image.

The process for determining focus of the lithography tool optionally further using the selected additional pattern group may further comprise summing the average absolute position offset of the first pattern group and the average absolute position offset of the additional pattern group to obtain a combined average absolute position offset. The predetermined relationship for the additional pattern group may be subtracted from the predetermined relationship for the first pattern group to obtain a combined predetermined relationship. The focus value may be derived based on the combined average absolute position offset and the combined predetermined relationship between focus value and average absolute position offset. The combined predetermined relationship may have the benefit of the combined average absolute position offset being up to twice as sensitive to changes in focus value compared to the predetermined relationship between focus value and amount of shift of the first pattern group. The use of a combination of different pattern groups may beneficially improve the ability to derive a sufficiently accurate focus value of the lithography tool.

The derived focus value may be used to determine whether the focus of the lithography tool is within an acceptable range of a target focus value. The focus of the lithography tool may be adjusted based on the derived focus value. For example, the focus of the lithography tool may be increased if the derived focus value is less than the target focus value, or the focus of the inspection tool may be decreased if the derived focus value is lower than the target focus value. In other words, if the amount of shift exceeds a predetermined threshold amount of shift, the sample may be considered unacceptable and may be discarded. The focus value of the lithography tool may be adjusted such that the amount of shift of features in samples subsequently produced using the lithography tool is decreased.

The method for determining focus of the lithography tool may further comprise verifying the adjusted focus. This may be achieved by forming a plurality of features on a further sample using the lithography tool, and imaging the further sample using the inspection tool to obtain an updated image. The amount of shift of the plurality of features in the updated image of the further sample, compared to the design layout, can then be determined from the updated image. Furthermore, an updated focus value may be derived based on the amount of shift determined from the updated image. The updated focus value may then be compared to a target focus value to determine whether or not the updated focus value is within the acceptable range of the target focus value. The process of deriving the focus value, verifying the focus value, and updating the focus value may be repeated iteratively until a focus value within the acceptable range of the target focus value is achieved.

The method for determining focus of the lithography tool may be partly automated. The method for determining focus of the lithography tool is desirably fully automated. A computer program may be provided which comprises instructions configured to control a charged particle system, comprising an inspection tool, to perform the method for determining focus of the lithography tool.

Embodiments include the following numbered clauses:
1. A computer-readable medium comprising instructions which, when executed by a computer, cause the computer to carry out a method of focus metrology, the method comprising:
   imaging, using an inspection tool, a sample having a plurality of features formed by a lithography tool;
   determining the amount of shift of the plurality of features in the image of the sample in comparison to a design layout; and
   deriving a focus value of the lithography tool based on the amount of shift.
2. The computer-readable medium of clause 1, wherein the plurality of features form a repeating pattern group on the sample.
3. The computer-readable medium of clause 2, wherein determining the amount of shift comprises comparing the position of the features in each instance of the pattern group in the image with the position of the corresponding features in each instance of the pattern group in the design layout to determine an average position offset of the features in each instance of the pattern group in the image.
4. The computer-readable medium of clause 3, wherein deriving the focus value is based on a predetermined relationship between focus value and amount of shift for the pattern group.
5. The computer-readable medium of clause 4, wherein the predetermined relationship is determined based on a simulation.
6. The computer-readable medium of clause 4, wherein the predetermined relationship is determined by
   generating a calibration sample by forming a plurality of features on a sample according to a design layout using a lithography tool set to a selected focus value;
   determining the amount of shift of the plurality of features for the pattern group in the calibration sample in comparison to the design layout;
   adjusting the selected focus value of the lithography tool; and
   repeating the generating, determining and adjusting steps a plurality of times to determine a relationship between the focus value and the amount of shift for the pattern group.
7. The computer-readable medium of clauses 4 to 6, wherein each instance of the pattern group comprises at least two adjacent features.
8. The computer-readable medium of clause 7, wherein the at least two adjacent features includes a central feature and an adjacent feature which is offset from the central feature in an orthogonal direction on the sample.
9. The computer-readable medium of clause 7, wherein the at least two adjacent features includes a central feature and an adjacent feature which is offset from the central feature in a diagonal direction on the sample.
10. The computer-readable medium of clauses 4 to 9, wherein the predetermined relationship is determined for a plurality of possible pattern groups, and wherein the pattern group is selected from the plurality of possible pattern groups based on sensitivity of focus value to amount of shift for each of plurality of possible pattern groups.
11. The computer-readable medium of clause 10, wherein the method further comprises selecting an additional pattern group from the plurality of different possible pattern groups, wherein the additional pattern group is selected based on the predetermined relationship for the additional pattern group being generally the inverse of the predetermined relationship for the pattern group.
12. The computer-readable medium of clause 11, wherein the method further comprises
   comparing the position of the features in each instance of the additional pattern group in the image with the position of the corresponding features in each instance of the additional pattern group in the design layout to determine an average position offset in each instance of the additional pattern group in the image;
   summing the average absolute position offset of the pattern group and the average absolute position offset of the additional pattern group to obtain a combined average absolute position offset;
   subtracting the predetermined relationship for the additional pattern group from the predetermined relationship for the pattern group to obtain a combined predetermined relationship;
wherein deriving the focus value is based on the combined average absolute position offset and the combined predetermined relationship between focus value and average absolute position offset.
13. The computer-readable medium of clauses 2 to 12, wherein the image depicts over 500 instances of the pattern group.
14. The computer-readable medium of clause 13, wherein the image depicts over 4,000 instances of the pattern group.
15. The computer-readable medium of any preceding clause, wherein the plurality of features are a plurality of contact holes defined by the sample.
16. The computer-readable medium of any preceding clause, wherein the method further comprises adjusting the focus of the lithography tool based on the derived focus value.
17. The computer-readable medium of clause 16, wherein the method further comprises verifying the adjusted focus by
   forming a plurality of features on a further sample using the lithography tool;
   imaging the further sample using the inspection tool to obtain an updated image;
   determining the amount of shift of the plurality of features in the updated image of the further sample in comparison to the design layout; and
   deriving the updated focus value of the lithography tool based on the amount of shift.
18. The computer-readable medium of any of the preceding clauses, wherein the inspection tool comprises a charged particle device.
19. The computer-readable medium of clause 18, wherein the charged particle device comprises a scanning electron microscope.
20. A computer-readable medium comprising instructions which, when executed by a computer, cause the computer to carry out a method of focus metrology, the method comprising:
   imaging, using an inspection tool, a sample having a plurality of features formed by a lithography tool;
   determining the error in placement of the plurality of features in the image of the sample in comparison to the placement position of the plurality of features in a design layout; and
   deriving a focus value of the lithography tool based on the error in placement.
21. A method of focus metrology, the method comprising:
   imaging, using an inspection tool, a sample having a plurality of features formed by a lithography tool;
   determining the amount of shift of the plurality of features in the image of the sample in comparison to a design layout; and
   deriving a focus value of the lithography tool based on the amount of shift.
22. A computer program comprising instructions configured to control a charged particle system, comprising the inspection tool, to perform the method of clause 21.
23. An assessment system comprising:
   an inspection tool configured to image a sample having a plurality of features formed by a lithography tool;
   an image processing unit configured to determine an amount of shift of the plurality of features in the image of the sample in comparison to a design layout; and
   a focus determination unit configured to derive a focus value of the lithography tool based on the amount of shift.
24. The assessment system of clause 23, further comprising a focus adjustment unit is configured to adjust a focus setting of the lithography tool based on the derived focus value.

Reference to a component or system of components or elements being controllable to manipulate a charged particle beam in a certain manner includes configuring a controller or control system or control unit to control the component to manipulate the charged particle beam in the manner described, as well optionally using other controllers or devices (e.g. voltage supplies and or current supplies) to control the component to manipulate the charged particle beam in this manner. For example, a voltage supply may be electrically connected to one or more components to apply potentials to the components, such as in a non-limited list the control lens array 250, the objective lens array 241, the condenser lens 231, correctors, a collimator element array and scan deflector array 260, under the control of the controller or control system or control unit. An actuatable component, such as a stage, may be controllable to actuate and thus move relative to another components such as the beam path using one or more controllers, control systems, or control units to control the actuation of the component.

The embodiments herein described may take the form of a series of aperture arrays or electron-optical elements arranged in arrays along a beam or a multi-beam path. Such electron-optical elements may be electrostatic. In an embodiment all the electron-optical elements, for example from a beam limiting aperture array to a last electron-optical element in a sub-beam path before a sample, may be electrostatic and/or may be in the form of an aperture array or a plate array. In some arrangements one or more of the electron-optical elements are manufactured as a microelectromechanical system (MEMS) (i.e. using MEMS manufacturing techniques). For example, the aperture arrays, plate electrodes of for example the objective lens array, one more features of the detector array, scan-deflector array and collimator element array, may be formed using MEMS manufacturing techniques.

References to upper and lower, up and down, above and below should be understood as referring to directions parallel to the (typically but not always vertical) upbeam and downbeam directions of the electron beam or multi-beam impinging on the sample 208. Thus, references to upbeam and downbeam are intended to refer to directions in respect of the beam path independently of any present gravitational field.

An assessment system according to an embodiment of the disclosure may be a tool which makes a qualitative assessment of a sample (e.g. pass/fail), one which makes a quantitative measurement (e.g. the size of a feature) of a sample or one which generates an image of map of a sample. Examples of assessment systems are inspection tools (e.g. for identifying defects), review tools (e.g. for classifying defects) and metrology tools, or tools capable of performing any combination of assessment functionalities associated with inspection tools, review tools, or metrology tools (e.g. metro-inspection tools). The electron-optical column 40 may be a component of an assessment system; such as an inspection tool or a metro-inspection tool, or part of an e-beam lithography tool. Any reference to a tool herein is intended to encompass a device, apparatus or system, the tool comprising various components which may or may not be collocated, and which may even be located in separate rooms, especially for example for data processing elements.

References to upper and lower, up and down, above and below should be understood as referring to directions parallel to the (typically but not always vertical) upbeam and downbeam directions of the electron beam or multi-beam impinging on the sample 208. Thus, references to upbeam and downbeam are intended to refer to directions in respect of the beam path independently of any present gravitational field.

The terms “sub-beam” and “beamlet” are used interchangeably herein and are both understood to encompass any radiation beam derived from a parent radiation beam by dividing or splitting the parent radiation beam. The term “manipulator” is used to encompass any element which affects the path of a sub-beam or beamlet, such as a lens or deflector.

References to elements being aligned along a beam path or sub-beam path are understood to mean that the respective elements are positioned along the beam path or sub-beam path.

While the present invention has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A computer-readable medium comprising instructions which, when executed by a computer, cause the computer to carry out operations for focus metrology, the operations comprising:
imaging, using an inspection tool or a metrology tool, a sample having a plurality of features formed by a lithography tool;
determining an amount of shift of the plurality of features in an image of the sample in comparison to a design layout; and
deriving a focus value of the lithography tool based on the amount of shift.

2. The computer-readable medium of claim 1, wherein the plurality of features form a repeating pattern group on the sample.

3. The computer-readable medium of claim 2, wherein determining the amount of shift comprises comparing a position of the features in each instance of the pattern group in the image with the position of the corresponding features in each instance of the pattern group in the design layout to determine an average position offset of the features in each instance of the pattern group in the image.

4. The computer-readable medium of claim 3, wherein deriving the focus value is based on a predetermined relationship between focus value and amount of shift for the pattern group.

5. The computer-readable medium of claim 4, wherein the predetermined relationship is determined based on a simulation.

6. The computer-readable medium of claim 4, wherein the predetermined relationship is determined by
generating a calibration sample by forming a plurality of features on a sample according to a design layout using a lithography tool set to a selected focus value;
determining the amount of shift of the plurality of features for the pattern group in the calibration sample in comparison to the design layout;
adjusting the selected focus value of the lithography tool; and
repeating the generating, determining and adjusting steps a plurality of times to determine a relationship between the focus value and the amount of shift for the pattern group.

7. The computer-readable medium of claim 4, wherein each instance of the pattern group comprises at least two adjacent features.

8. The computer-readable medium of claim 7, wherein the at least two adjacent features includes a central feature and an adjacent feature which is offset from the central feature in an orthogonal direction on the sample.

9. The computer-readable medium of claim 7, wherein the at least two adjacent features includes a central feature and an adjacent feature which is offset from the central feature in a diagonal direction on the sample.

10. The computer-readable medium of claim 4, wherein the predetermined relationship is determined for a plurality of possible pattern groups, and wherein the pattern group is selected from the plurality of possible pattern groups based on sensitivity of focus value to amount of shift for each of plurality of possible pattern groups.

11. The computer-readable medium of claim 10, wherein the operations further comprise selecting an additional pattern group from the plurality of possible pattern groups, wherein the additional pattern group is selected based on the predetermined relationship for the additional pattern group being generally the inverse of the predetermined relationship for the pattern group.

12. The computer-readable medium of claim 11, wherein the operations further comprise
comparing the position of the features in each instance of the additional pattern group in the image with the position of the corresponding features in each instance of the additional pattern group in the design layout to determine an average position offset in each instance of the additional pattern group in the image;
summing the average absolute position offset of the pattern group and the average absolute position offset of the additional pattern group to obtain a combined average absolute position offset;
subtracting the predetermined relationship for the additional pattern group from the predetermined relationship for the pattern group to obtain a combined predetermined relationship;
wherein deriving the focus value is based on the combined average absolute position offset and the combined predetermined relationship between focus value and average absolute position offset.

13. The computer-readable medium of claim 2, wherein the image depicts over 500 instances of the pattern group.

14. The computer-readable medium of claim 13, wherein the image depicts over 4,000 instances of the pattern group.

15. The computer-readable medium of claim 1, wherein the plurality of features are a plurality of contact holes defined by the sample.

16. The computer-readable medium of claim 1, wherein the operations further comprise adjusting the focus of the lithography tool based on the derived focus value.

17. The computer-readable medium of claim 16, wherein the operations further comprise verifying the adjusted focus by
forming a plurality of features on a further sample using the lithography tool;
imaging the further sample using the inspection tool or the metrology tool to obtain an updated image;
determining the amount of shift of the plurality of features in the updated image of the further sample in comparison to the design layout; and
deriving an updated focus value of the lithography tool based on the amount of shift.

18. The computer-readable medium of claim 1, wherein the inspection tool comprises a charged particle device.

19. The computer-readable medium of claim 18, wherein the charged particle device comprises a scanning electron microscope.

20. A computer-readable medium comprising instructions which, when executed by a computer, cause the computer to carry out operations of focus metrology, the operations comprising:
imaging, using an inspection tool or a metrology tool, a sample having a plurality of features formed by a lithography tool;
determining an error in placement of the plurality of features in the image of the sample in comparison to the placement position of the plurality of features in a design layout; and
deriving a focus value of the lithography tool based on the error in placement.
